(19) United States
(12) Patent Application Publication
(10) Pub. No.: US 2015/0228555 A1
(43) Pub. Date: Aug. 13, 2015

(54) STRUCTURE AND METHOD OF CANCELLING TSV-INDUCED SUBSTRATE STRESS

(71) Applicant: GLOBALFOUNDRIES INC., Grand Cayman (KY)

(72) Inventors: Mohamed A. RABIE, Mechanicville, NY (US); Premachandran CHIRAYARIKATHUVEEDU, Clifton Park, NY (US); Mahadeva Iyer NATARAJAN, Clifton Park, NY (US)

(73) Assignee: GLOBALFOUNDRIES INC., Grand Cayman (KY)

(21) Appl. No.: 14/176,178

(22) Filed: Feb. 10, 2014

(51) Int. Cl. H01L 23/48; H01L 21/321; H01L 21/324; H01L 21/768; H01L 23/00

(52) U.S. Cl. CPC H01L 23/481; H01L 21/76898; H01L 23/562; H01L 21/324; H01L 21/7684; H01L 21/32115

(57) ABSTRACT

Structures and methods of fabrication are provided with reduced or cancelled stress within the substrate of the structure adjacent to a through-substrate via. The fabrication method(s) includes: forming a structure with a through-substrate via (TSV) having a reduced device keep-out zone (KOZ) adjacent to the through-substrate via, the forming including: providing the through-substrate via within a substrate of the structure; and providing a stress-offset layer above the substrate selected and configured to provide a desired offset stress to reduce stress within the substrate caused by the presence of the through-substrate via within the substrate. In one embodiment, the stress-offset layer provides a desired compressive stress sufficient to reduce or eliminate tensile stress within the substrate due to the presence of the through-substrate via within the substrate.

### BACKGROUND OF THE INVENTION

The present invention relates to integrated circuit devices and methods of fabrication, and more particularly, to circuit structures with through-substrate vias (TSVs), and manufacturing methods thereof.

In recent years, the features of modern, ultra-high density integrated circuits have steadily decreased in size in an effort to enhance overall speed, performance, and functionality of circuits. As a result, the semiconductor industry continues to experience tremendous growth due to significant and ongoing improvements in integration density of a variety of electronic components, such as transistors, capacitors, diodes, and the like. These improvements have primarily come about due to a persistent and successful effort to reduce the critical dimension (i.e., minimum feature size) of components, directly resulting in the ability of process designers to integrate more and more components into a given area of a semiconductor chip.

Improvements in integrated circuit design have been essentially two-dimensional (2D); that is, improvements have been related primarily to the layout of the circuit on the surface of a semiconductor chip. However, as device features are continuing to be aggressively scaled, and more semiconductor components are being placed onto the surface of a single chip, the required number of electrical interconnects necessary for circuit functionality dramatically increases, resulting in an overall circuit layout that is increasingly becoming more complex and densely packed. Furthermore, even though improvements in photolithography processes have yielded significant increases in integration densities of 2D circuit designs, simple reduction in feature size is rapidly approaching limits of what can presently be achieved in only two dimensions.

As the number of electronic devices on single chips rapidly increases, three-dimensional (3D) integrated circuit layouts, or stacked chip designs, have been utilized for certain semiconductor devices in an effort to overcome the feature size and density limitations associated with 2D layouts. Typically, in a 3D integrated circuit design, two or more semiconductor dies are bonded together, and electrical connections are formed between each die. One method of facilitating the chip-to-chip electrical connections is by use of so-called through-substrate vias (TSVs) or through-silicon vias. A TSV is a vertical electrical connection that passes through a silicon wafer or die, allowing for more simplified interconnection of vertically aligned electronic devices, thereby significantly reducing integrated circuit layout complexity as well as overall dimensions of a multi-chip circuit. Some of the benefits associated with the interconnect technology enabled by 3D integrated circuit designs include accelerated data exchange, reduced power consumption, and much higher input/output voltage densities. One disadvantage, however, is the need for keep-out zones (KOZs) adjacent to the through-substrate vias necessitated by, for instance, a coefficient of thermal expansion mismatch between the through-substrate via conductor and the substrate material.

### BRIEF SUMMARY

The shortcomings of the prior art are overcome and additional advantages are provided through the provision, in one aspect, of a method which includes forming a structure with a through-substrate via (TSV) and a reduced device keep-out zone (KOZ) adjacent to the through-substrate via. The forming includes: providing the through-substrate via within a substrate of the structure; and providing a stress-offset layer above the substrate selected and configured to provide a desired offset stress to reduce stress within the substrate caused by the presence of the through-substrate via within the substrate.

In another aspect, a structure is provided which includes: a substrate; a through-substrate via (TSV) extending through the substrate; a device disposed adjacent to the through-substrate via without a thermal stress-necessitated, keep-out zone disposed between the through-substrate via and the device; and a stress-offset layer above the substrate. The stress-offset layer provides a desired offset stress to cancel thermally-induced stress in the substrate adjacent to the through-substrate via, and thereby eliminate any need for the thermal-stress-necessitated, keep-out zone between the through-substrate via and the device.

Additional features and advantages are realized through the techniques of the present invention. Other embodiments and aspects of the invention are described in detail herein and are considered a part of the claimed invention.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIGS. 1A-1F illustrate one process flow for forming circuit structures with through-substrate vias (TSVs), in accordance with one or more aspects of the present invention;

FIG. 2A is a partial plan view of a circuit structure having a through-substrate via with a conventional device keep-out zone (KOZ) separating the through-substrate via and device region, and which is to be modified in accordance with one or more aspects of the present invention;

FIG. 2B is an elevational view of the circuit structure of FIG. 1F, with the device keep-out zone of FIG. 2A shown separating the through-substrate via from the device region, and which is to be modified in accordance with one or more aspects of the present invention;

FIG. 2C is a typical graphical depiction of change in I_{ON} versus size of device keep-out zone;

FIG. 3A depicts a modified circuit structure, wherein the device keep-out zone is reduced, or even eliminated, between the through-substrate via and the adjacent one or more devices of the structure, in accordance with one or more aspects of the present invention;

FIG. 3B is an elevational view of an alternate embodiment of a circuit structure with a reduced or eliminated device keep-out zone, in accordance with one or more aspects of the present invention;

FIG. 3C depicts the circuit structure of FIG. 3B, and illustrates thermally-induced stresses within the circuit structure, one or more of which are designed to balance thermally-induced stress within the substrate due to the presence of the through-substrate via within the substrate, in accordance with one or more aspects of the present invention; and

FIGS. 4A-4F illustrate, in part, one middle-of-line process flow for forming a circuit structure with one or more through-substrate vias (TSVs) and a stress-offset layer, in accordance with one or more aspects of the present invention.

### DETAILED DESCRIPTION

Aspects of the present invention and certain features, advantages, and details thereof, are explained more fully below with reference to the non-limiting examples illustrated in the accompanying drawings. Descriptions of well-known materials, fabrication tools, processing techniques, etc, are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

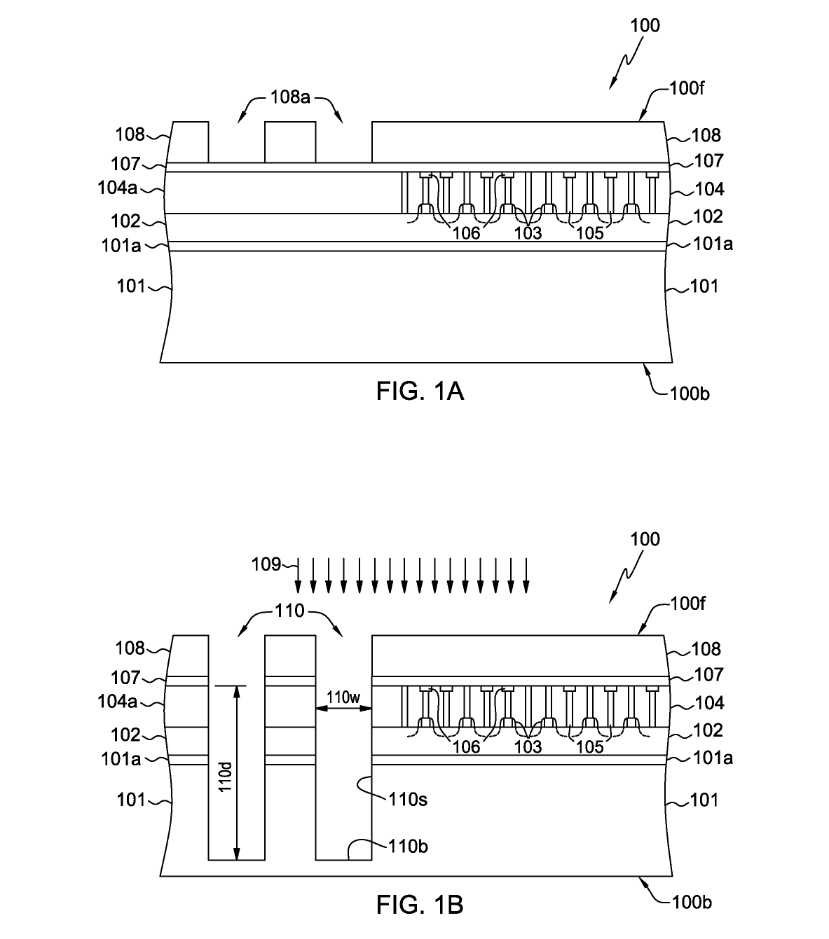

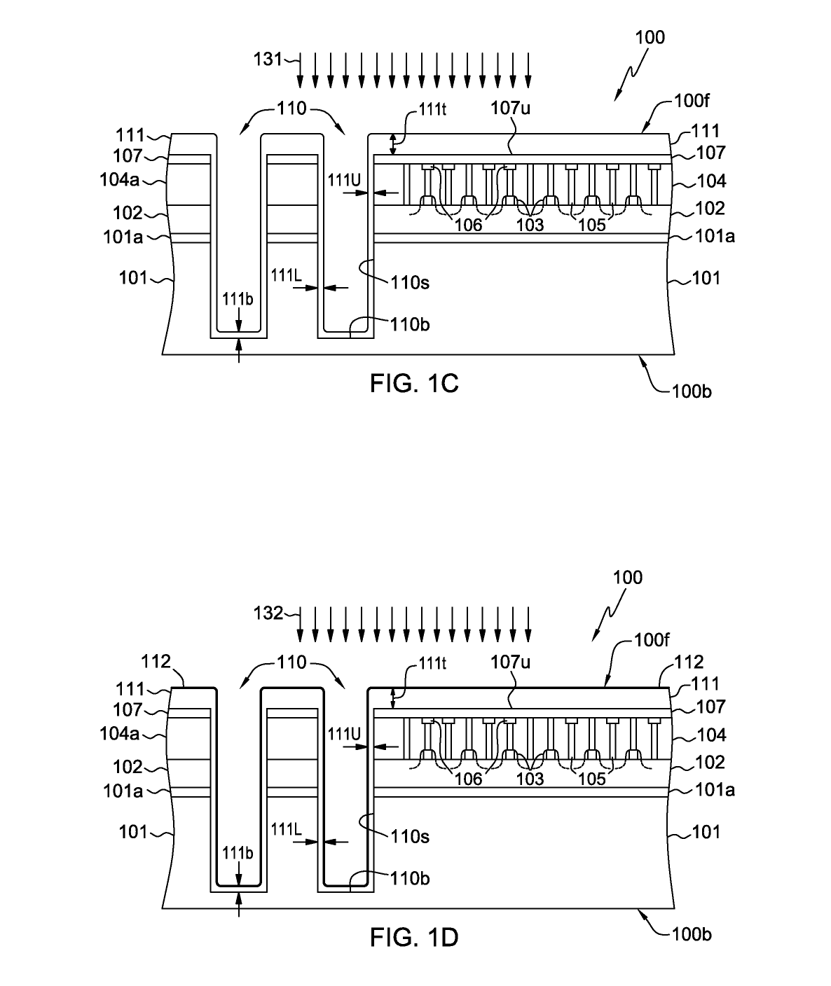

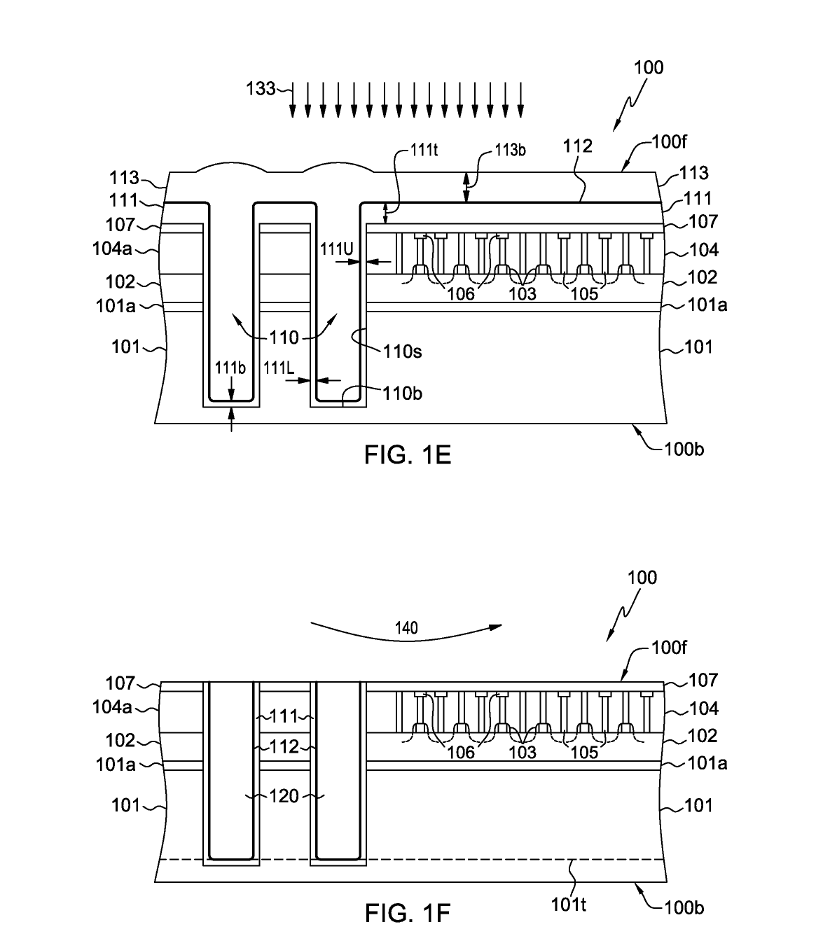

Through-substrate vias (TSVs) can be integrated into virtually any phase of semiconductor device manufacturing, including via-first, via-middle, and via-last approaches. Currently, most integration development has tended to focus on forming TSVs within an active area of the semiconductor die (e.g., via-middle and via-last schemes). One process for forming TSVs based on a via-middle approach, wherein the TSVs are formed after transistor and contact element formation, is illustrated in FIGS. 1A-1F.

FIG. 1A is a schematic cross-sectional view depicting one stage in one example of a via-middle integration scheme used in the formation of a TSV in accordance with one or more aspects of the present invention. As shown in FIG. 1A, a semiconductor chip or wafer 100 may include a substrate 101, which may represent any appropriate carrier material above which may be formed a semiconductor layer 102. Additionally, a plurality of schematically depicted active and/or passive circuit elements 103, such as transistors, capacitors, resistors and the like, may be formed in or above the semiconductor layer 102, in which case the semiconductor layer 102 may also be referred to as a device layer 102. Depending on the overall design strategy of the wafer 100, the substrate 101 may in some embodiments have or be a substantially crystalline substrate material (i.e., bulk silicon), whereas in other embodiments, substrate 101 may be formed on the basis of a silicon-on-insulator (SOI) architecture, in which a buried insulating layer 101a may be provided below device layer 102. It should be appreciated that the semiconductor/device layer 102, even if including a substantially silicon-based material layer, may include other semiconducting materials, such as germanium, carbon and the like, in addition to appropriate dopant species for establishing the requisite active region conductivity type for the circuit elements 103.

FIG. 1A also illustrates a contact structure layer 104, which may be formed above device layer 102 to provide electrical interconnects between circuit elements 103 and a metallization layer or system (not shown) to be formed above device layer 102 during subsequent processing steps. For example, one or more interlayer dielectric (ILD) layers 104a may be formed above the device layer 102 so as to electrically isolate the respective circuit elements 103. The ILD layer 104a may include, for example, silicon dioxide, silicon nitride, silicon oxynitride, and the like, or a combination of these commonly used dielectric materials. Thereafter, the ILD layer 104a may be patterned to form a plurality of via openings, each of which may be filled with a suitable conductive material such as tungsten, copper, nickel, silver, cobalt or the like (as well as alloys thereof), thereby forming contact vias 105. Additionally, in some embodiments, one or more trench openings may also be formed in the ILD layer 104a above one or more of the vias openings noted above. Thereafter, depending on the specified processing parameters, any trenches formed in the ILD layer 104a may be filled in a common deposition step with a similar conductive material such as noted for the contact vias 105 above, thereby forming conductive lines 106 as may be required by the device requirements.

As shown in FIG. 1A, in certain embodiments, a hardmask layer 107, which may act as a protective layer for the underlying layer during an ashing process of a photoresist mask layer 108, may thereafter be formed above the contact structure layer 104. Hardmask layer 107 may include a dielectric material having an etch selectivity relative to at least the material including the upper surface portion of the ILD layer 104a, such as silicon nitride (SiN), silicon oxynitride (SiON), silicon carbide (SiC), silicon carbonitride (SiCN) and the like. In some illustrative embodiments, hardmask layer 107 may be formed above the contact structure layer 104 by performing a suitable deposition processes based on parameters well known in the art, such as a chemical vapor deposition (CVD) process, a physical vapor deposition (PVD) process, atomic layer deposition (ALD), spin on coating, and the like. Thereafter, a patterned resist mask layer 108 may be formed above hardmask layer 107 based on typical photolithography processes, such as exposure, baking, developing, and the like, so as to provide openings 108a in mask layer 108, exposing hardmask layer 107.

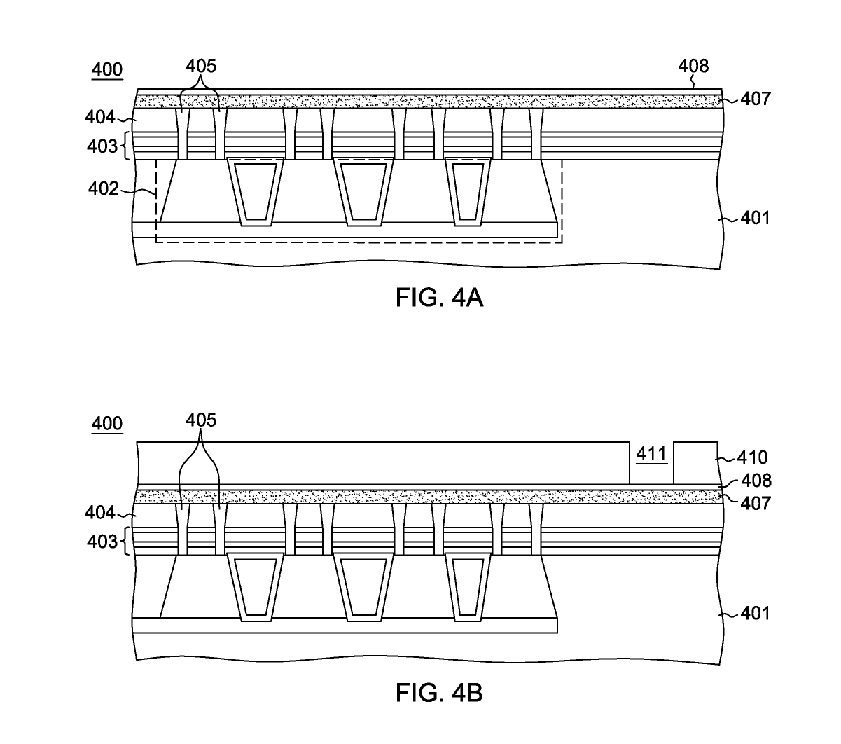

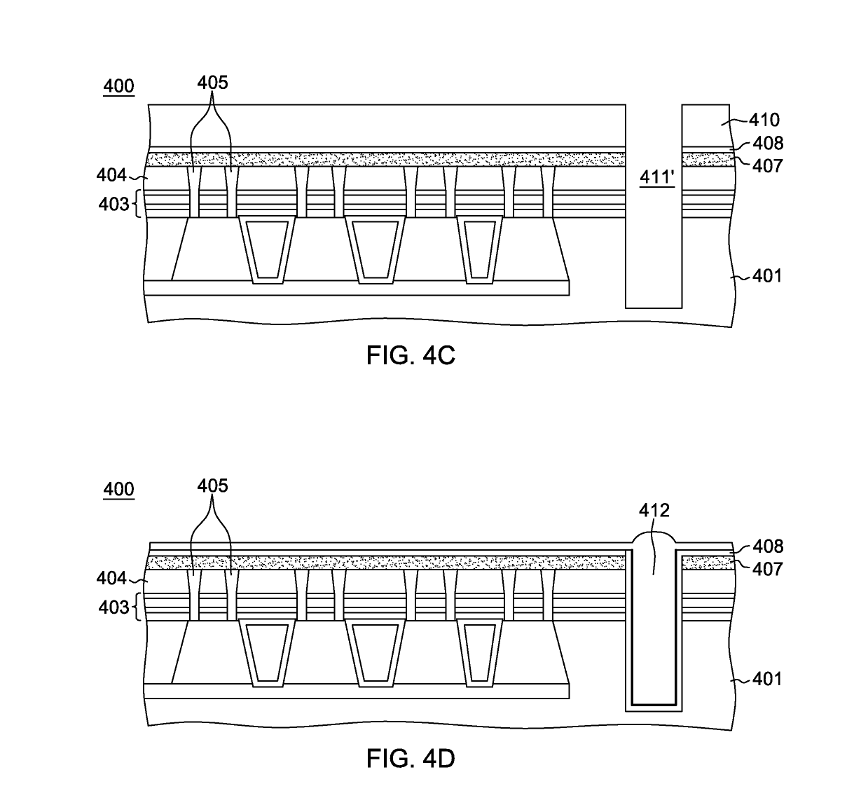

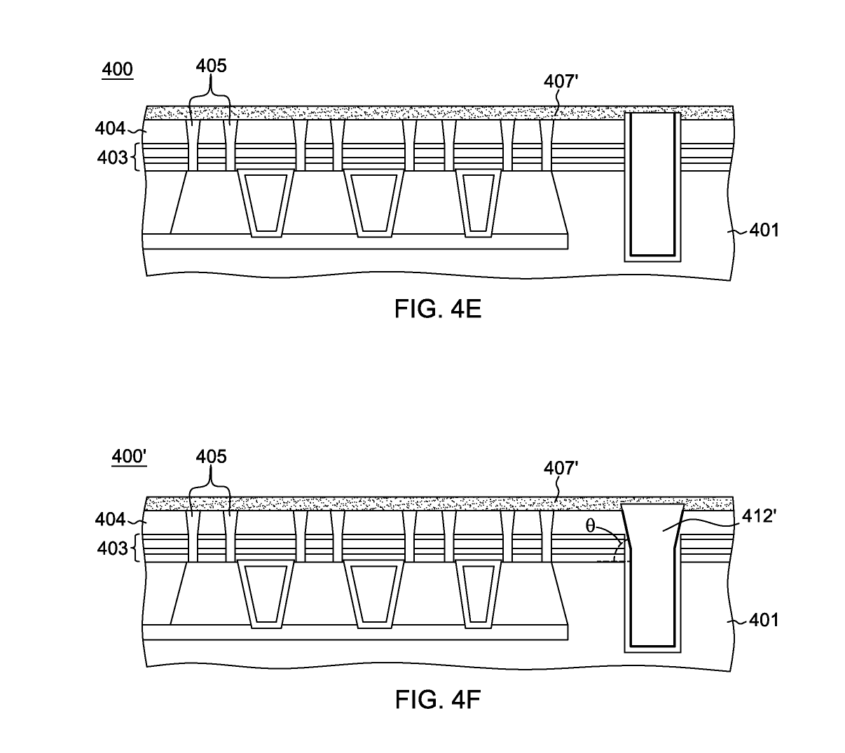

FIG. 1B shows the structure of FIG. 1A in a further manufacturing stage, wherein an etch process 109 is performed to create TSV openings 110 in wafer 100. As shown in FIG. 1B, the patterned resist mask layer 108 may be used as an etch mask during the etch process 109 to form openings in the hardmask layer 107, and to expose the ILD layer 104a of the contact structure layer 104. Thereafter, the etch process 109 may be continued, and the patterned mask layer 108 and patterned hardmask layer 107 may be used as mask elements to form the TSV openings 110 through the contact structure layer 104, through the device layer 102, and into the substrate 101. In certain embodiments, the etch process 109 may be a substantially anisotropic etch process, such as a deep reactive ion etch (RIE), and the like. Depending on the chip design considerations and etch parameters employed during the etch process 109, the sidewalls 110s of the TSV openings 110 may be substantially vertical with respect to the front and back surfaces 100f, 100b of the wafer 100 (as shown in FIG. 1B), whereas in some embodiments the sidewalls 110s may be slightly tapered, depending on the depth of the TSV openings 110 and the specific etch recipe used to perform the etch process 109. Moreover, since the TSV openings 110 may pass through and/or into a plurality of different material layers, such as the ILD layer 104a, the device layer 102, a buried insulation layer 101a (when used), and substrate 101, the etch process 109 may be substantially non-selective with respect to material type, such that a single etch recipe may be used throughout the duration of the etch. In other illustrative embodiments, however, the etch process 109 may include a plurality of different etch recipes, each of which may be substantially selective to the material layer then being etched. In some embodiments, the top entrant of the TSV can be tilted from the upper surface of the Middle of Line (MOL) layers reaching down to the device layer. The tilt angle θ can be, by way of example, in the range from 90 to 45 degrees (see, in this regard, the example of FIG. 4F).

Depending on the overall processing and chip design parameters, the openings 110 may have a width dimension 110w ranging from 1-10 μm, a depth dimension 110d ranging from 5-50 μm or even more, and an aspect ratio—i.e., depth-to-width ratio—ranging between 4 and 25. In one embodiment, the width dimension 110w may be approximately 5 μm, the depth dimension 110d may be approximately 50 μm, and the aspect ratio may be approximately 10. Typically, however, and as shown in FIG. 1B, the TSV openings 110 do not, at this stage of fabrication, extend through the full thickness of the substrate 101, but instead stop short of the back surface 100b of the wafer 100. For example, in some embodiments, the etch process 109 is continued until the bottom surfaces 110b of the TSV openings 110 come within a range of approximately 1-700 μm of the back surface 100b. Additionally, and as will be discussed in further detail below, after the completion of processing activities above the front side 100f of the wafer 100, such as processing steps to form a metallization system (i.e., metal layers) above the contact structure layer 104 and the like, the wafer 100 is thinned from the back side 100b to expose the finished TSVs 120 (see FIG. 1F).

FIG. 1C shows the structure of FIG. 1B after the patterned resist mask layer 108 has been removed from above the hardmask layer 107. Depending on the overall chip configuration and design considerations, an isolation layer 111 may be formed on or adjacent to the exposed surfaces of the TSV openings 110 so as to eventually electrically isolate the finished TSVs 120 (see FIG. 1F) from substrate 101, device layer 102, and/or contract structure layer 104. As shown in FIG. 1C, isolation layer 111 may be formed above all exposed surfaces of wafer 100, including the upper surface 107u of hardmask layer 107, and the sidewall and bottom surfaces 110s, 110b of TSV openings 110. It should be noted that, depending on the overall device requirements and processing scheme, an intervening material layer (not shown), such as an adhesion layer or barrier layer, or the like, may be deposited between isolation layer 111 and surfaces 110s, 110b. In certain embodiments, the isolation layer 111 may be formed by performing a suitable conformal deposition process 131 designed to deposit an appropriate dielectric insulating material layer having a substantially uniform thickness on the exposed surfaces of the TSV openings 110. It should be noted, however, that the as-deposited thickness of isolation layer 111 may vary to a greater or lesser degree, depending on the specific location and the orientation of the surface onto which it is deposited.

For example, in some embodiments, isolation layer 111 may be formed of silicon dioxide, and the deposition process 131 may be any one of several deposition techniques well known in the art, such as low-pressure chemical vapor deposition (LPCVD), sub-atmospheric-pressure chemical vapor deposition (SACVD), plasma-enhanced chemical vapor deposition (PECVD), and the like. In certain embodiments, isolation layer 111 may include silicon dioxide, and may be deposited based on tetraethylorthosilicate (TEOS) and O₃ (ozone) using LPCVD, SACVD or PECVD processes. Additionally, the minimum required as-deposited thickness of the isolation layer 111 may be established as necessary to ensure that the TSV 120 (see FIG. 1F) is electrically isolated from the surrounding layers of wafer 100. For example, in order to ensure proper surface coverage and layer functionality, the minimum required thickness of isolation layer 111 at any point within TSV openings 110 may be on the order of approximately 100-200 nm, whereas in specific embodiments the minimum thickness may be approximately 150 nm. However, as noted previously, even though a substantially conformal deposition process may be used to form isolation layer 111, the as-deposited thickness of the isolation layer 111 may vary to a greater or lesser degree, depending on the specific location and orientation of the surface where isolation layer 111 may be deposited.

For example, the as-deposited thickness of isolation layer 111 may vary from a thickness 111t above upper surface 107u of hardmask layer 107, to a thickness 111U near the upper portion of the TSV sidewall 110s, to a thickness 111L near the lower portion of the TSV sidewall 110s, to a thickness 111b at the bottom surface 110b of the TSV opening 110. Furthermore, depending on the type of deposition process utilized and the coverage efficiency obtained, the as-deposited thicknesses 111t, 111U, 111L and 111b may vary from greatest to least by a factor of 2, 3, 4 or even more. For example, when 50% coverage efficiency is obtained when depositing isolation layer 111, the least as-deposited thickness may be approximately 50% of the greatest as-deposited thickness; that is, varying by a factor of 2. Similarly, when the coverage efficiency is 33%, the greatest and least as-deposited thickness may vary by a factor of approximately 3, and when the coverage efficiency is 25% or less, the as-deposited thicknesses of the isolation layer 111 may vary by a factor of approximately 4 or more.

FIG. 1D depicts the structure of FIG. 1C after a barrier layer 112 has been formed above wafer 100. In some embodiments, barrier layer 112 may serve to prevent the conductive material including the finished TSVs 120 (see FIG. 1F) from diffusing into and/or through isolation layer 111, or into and/or through ILD layer 104a, a situation that could significantly affect overall performance of the circuit elements 103, the contact vias 105, and/or the conductive lines 106. Furthermore, barrier layer 112 may also act as an adhesion layer, thereby potentially enhancing that overall bond between the contact material of the finished TSVs 120 and the underlying dielectric isolation layer 111.

As shown in FIG. 1D, barrier layer 112 may be formed above all exposed surfaces of isolation layer 111, including the exposed surfaces inside of TSV openings 110. In certain illustrative embodiments, barrier layer 112 may be deposited above isolation layer 111 by performing a substantially conformal deposition process 132, such as CVD, PVD, ALD (atomic layer deposition) and the like. Depending on device requirements and TSV design parameters, barrier layer 112 may include any one of a number of suitable barrier layer materials well known in the art to reduce and/or resist diffusion of metal into a surrounding dielectric, such as tantalum (Ta), tantalum nitride (TaN), titanium (Ti), titanium nitride (TiN), titanium silicon nitride (TiSiN), tungsten nitride (WN), and the like. Furthermore, due to the relatively large width 110w of the TSV openings 110 as compared to a contact via used to form an electrical interconnection to a typical integrated circuit element (such as the contact vias 105), the thickness of barrier layer 112 may not be critical to the overall performance characteristics of the TSVs 120 (see FIG. 1F). Accordingly, the thickness of barrier layer 112 may in some illustrative embodiments range between 20 nm and 200 nm, depending on the material type and deposition method used to form barrier layer 112.

After barrier layer 112 has been formed above exposed surfaces of isolation layer 111, a layer of conductive contact material 113 may then be formed above wafer 100 so as to completely fill TSV openings 110, as shown in FIG. 1E. Depending on the TSV design requirements, the layer of conductive contact material 113 may be, for instance, a conductive metal such copper, and the like, or in certain embodiments may include a suitable copper metal alloy. In some embodiments, TSV openings 110 may be filled with the layer of conductive contact material 113 based on a substantially “bottom-up” deposition process 133 well known to those skilled in the art, such as a suitably designed electrochemical plating (ECP) process and the like, thereby reducing the likelihood that voids are formed and/or trapped in the finished TSVs 120 (see FIG. 1F). In other illustrative embodiments, an electroless plating process may be employed. Additionally, and depending on the type of material used for barrier layer 112 and the type of deposition process 133 used to fill the TSV openings 110, a seed layer (not shown) may be formed on barrier layer 112 prior to performing the deposition process 133. In certain embodiments, the optional seed layer may be deposited using a highly conformal deposition process, such as sputter deposition, ALD, or the like, and may have a thickness ranging from approximately 5-10 nm. However, in other illustrative embodiments, the thickness of barrier layer 133 may be even greater, for example, from 10-15 nm, whereas in still other embodiments, the thickness may be even less, for example, from 1-5 nm. Depending on the processing requirements, still other barrier layer thicknesses may be used.

A significant amount of material “overburden” 113b, or additional thickness, may need to be deposited outside of the TSV openings 110 and above the upper horizontal surfaces of the wafer 100 to ensure that the TSV openings 110 are completely filled with the layer of conductive contact material 113. Depending on the width 110w, depth 110d, and aspect ratio of the TSV openings 110, the overburden 113b may, in some illustrative embodiments, be greater than 2 nm, and may range as high as 4-5 μm, or even greater.

In those process recipes wherein the layer of conductive contact material 113 includes an electroplated copper and/or copper alloy, wafer 100 shown in FIG. 1E may be exposed to a heat treatment process after the layer of conductive contact material 113 has been formed, so as to facilitate grain growth and stabilization of the copper film characteristics. For example, the heat treatment process may be an annealing process performed under atmospheric pressure conditions at a temperature ranging between 100° C. and 450° C., and for a time of 1 hour or less. Depending on the overall integration scheme and thermal budget of the wafer 100, other heat treatment recipes may also be employed.

FIG. 1F shows the structure of FIG. 1E in a further advanced manufacturing stage. As shown in FIG. 1F, a planarization process 140, such as a CMP process and the like, may be performed to remove the horizontal portion of the layer of conductive contact material 113 formed outside of the TSV openings 110 from above the wafer 100. Furthermore, in some embodiments the horizontal portions of isolation layer 111 formed above wafer 100 and outside of TSV openings 110 (FIG. 1E) may also be removed during the planarization process 140. Moreover, the thickness of the hardmask layer 107, which as noted previously may act as a CMP stop layer, may also be reduced during the planarization process 140. After completion of the planarization process 140, additional processing of the front side 100f of the wafer 100 may be performed, such as forming metallization layers and the like above the TSV's 120 and contact structure layer 104. Thereafter, wafer 100 may be thinned from the back side 100b so as to reduce the thickness of the substrate 101 (indicated in FIG. 1F by dashed line 101t) and expose the bottom surfaces 120b of the TSVs 120 in preparation for wafer stacking and substrate bonding, that is, 3-D integrated circuit assembly.

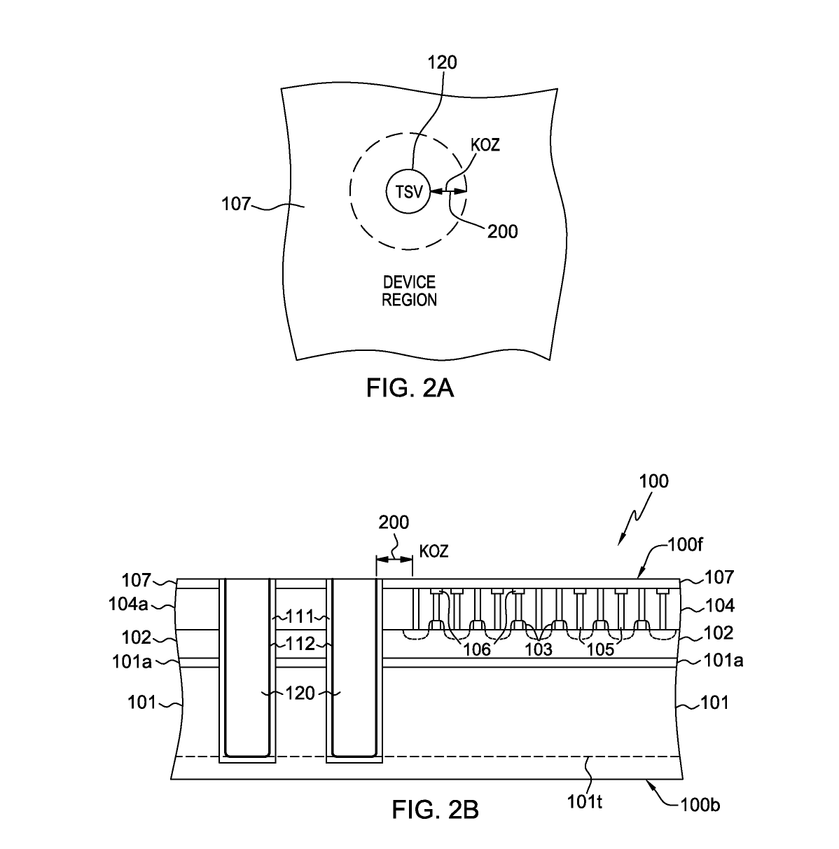

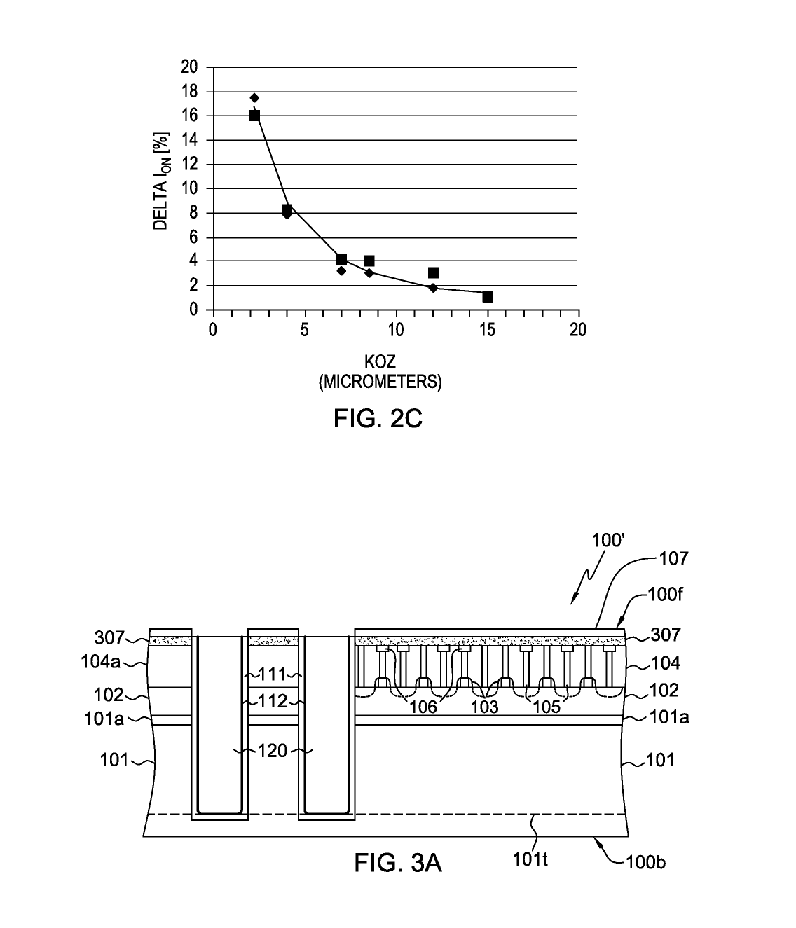

As noted, a post-TSV deposition anneal step may be desired (or required) to increase grain size of the through-substrate via conductive material, such as polycrystalline copper, to enhance electrical conductivity, as well as minimize copper protrusion during subsequent back-end-of-line (BEOL) processing. This anneal step may result in significant tensile stress in device layer 102, particularly during cool-down due to the different coefficients of thermal expansion (CTE) of the through-substrate via (e.g., copper), and the device substrate (e.g., a semiconductor material including silicon). The resultant stresses in the proximity of the through-substrate via could impact the adjacent devices of device layer 102 if close enough to the TSV by, for instance, effecting mobility of carriers, as well as the semiconductor band gap (e.g., silicon band gap). This possibility typically imposes a limitation on the acceptable distance between the through-substrate via and the devices of the device region of the wafer, which is referred to as the device keep-out zone (KOZ) 200, and is illustrated in plan and perspective views in FIGS. 2A, and 2B, respectively (using, with respect to FIG. 2B, the structure of FIG. 1F). Currently, the smallest reported KOZ is approximately 5-7 μm, at which point, the I_{ON} of a transistor device is degraded less than 5%, which is considered acceptable.

By way of example, FIG. 2C graphically illustrates change in I_{ON} with distance from a through-substrate via within a device layer of a structure with, for instance, a through-substrate via including copper, and a hardmask layer (or etch-stop layer) 107 (FIG. 2B) including SiC. As shown, in order to achieve a ΔI_{ON} less than 5%, the device keep-out zone (KOZ) around the TSV should be at least 6-7 μm. This is a continuing constraint for circuit designers, and results in inefficient device layer use in the region of the through-substrate via(s).

By significantly reducing the device KOZ, or even eliminating the KOZ, additional device layer space will be obtained to provide additional devices in the region of the TSV(s), and thus more functionality per chip.

Generally stated, disclosed herein are structures and methods of fabrication which have substantially reduced (or fully canceled) stress within the substrate of the structure, particularly adjacent to the through-substrate via(s). In one embodiment, stress is reduced (or eliminated) within a device layer of the substrate by providing a stress-offset layer above the substrate selected and configured (e.g., sized) to provide a desired offset stress to reduce stress within the substrate caused by the presence of the through-substrate via within the substrate. By appropriately selecting and configuring the stress-offset layer above the substrate, the conventional device keep-out zone (KOZ) can be reduced (or even eliminated) around a through-substrate via, for instance, in planar CMOS technology.

More particularly, in one embodiment, provided herein is a method which includes: forming a structure with a through-substrate via (TSV) and a reduced device keep-out zone (KOZ) adjacent to the through-substrate via. The forming includes: providing the through-substrate via within a substrate of the structure; and providing a stress-offset layer above the substrate selected and configured to provide a desired offset stress to reduce stress within the substrate caused by the presence of the through-substrate via within the substrate. For instance, providing the stress-offset layer may include selecting a material for the stress-offset layer which establishes a desired offset stress within the substrate sufficient to reduce or substantially eliminate a stress within the substrate caused by the presence of the through-substrate via (TSV) within the substrate. In one example, the induced stress is a thermally-induced compressive stress, and the TSV-induced stress a thermally-induced tensile stress due, for instance, to mismatches in coefficients of thermal expansion of the respective materials.

In one embodiment, the forming further includes annealing the structure, wherein post-annealing, the stress-offset layer shrinks at a faster rate than the substrate, and therefore provides a compressive stress within the substrate which offsets a tensile stress within the substrate adjacent to the through-substrate via. By way of example, the substrate may be, or include, a semiconductor material, and there may be a coefficient of thermal expansion mismatch between the stress-offset layer and the substrate which is close to the coefficient of thermal expansion mismatch between the through-substrate via material and the substrate. For instance, the coefficient of thermal expansion (CTE) of copper TSV is about 17 ppm/° C., and the CTE of a silicon substrate is about 2.3 ppm/° C. In one embodiment, the stress-offset layer may be a nitrogen-doped and hydrogen-doped silicon carbide material, such as N-Blok (also referenced to as nitride barrier for low K), which typically has 10% mol to about 25% mol of nitrogen dopant, and which may be deposited using, for instance, chemical vapor deposition (CVD) processing. The coefficient of thermal expansion of N-Blok is about 11 ppm/° C. Note that this is a much higher CTE than the typical silicon carbide hardmask, which is about 4 ppm/° C. In addition, to facilitate the stress-offset, the product of the CTE of the stress-offset layer and the elasticity modulus of the substrate should be at least 1.5 times greater than the product of the CTE of the substrate and the elasticity modulus of the stress-offset layer. For instance, the elasticity modulus of the stress-offset layer may be less than about 200 MPa. In some advantageous implementations, the elasticity modulus of the stress-offset layer, such as N-Blok, is less than 200 Mpa. N-Blok elemental composition is Si_{w}CₓN_{y}H_{z}, where w+x+y+z=1.0.

In one embodiment, the stress-offset layer is selected or tailored to provide the desired offset stress within the substrate which substantially cancels out any stress within the substrate produced by the presence of the through-substrate via during circuit fabrication, as well as during operation of the structure. For instance, any thermally-induced stress within the substrate due to the presence of the through-substrate via(s), or even intrinsic stress within the substrate due to middle-of-line (MOL) layers, may be canceled in this manner. By way of further example, forming the structure may also include polishing the structure, and stopping the polishing on the stress-offset layer, in which case, the stress-offset layer is also designed as an etch-stop layer for the polishing of the structure.

Also disclosed hereinbelow is a novel structure which includes a substrate, a through-substrate via (TSV) extending through the substrate, a device located directly adjacent to the through-substrate via without a thermal stress-necessitated, keep-out zone (KOZ) disposed between the through-substrate via and the device, and a stress-offset layer. The stress-offset layer is located above the substrate, and provides a desired offset stress to cancel thermally-induced stress within the substrate due to the presence of the through-substrate via within the substrate, and thereby, eliminate any need for a thermal stress-necessitated, keep-out zone between the through-substrate via and the device. By way of example, the device may be disposed within five microns or less (e.g., about 3 microns or less) of the through-substrate via, which has conventionally been not achievable without severely impacting device performance. Note that “device” in this context refers to any active or passive device, with a transistor being one example of a device to be located directly adjacent to the through-substrate via(s).

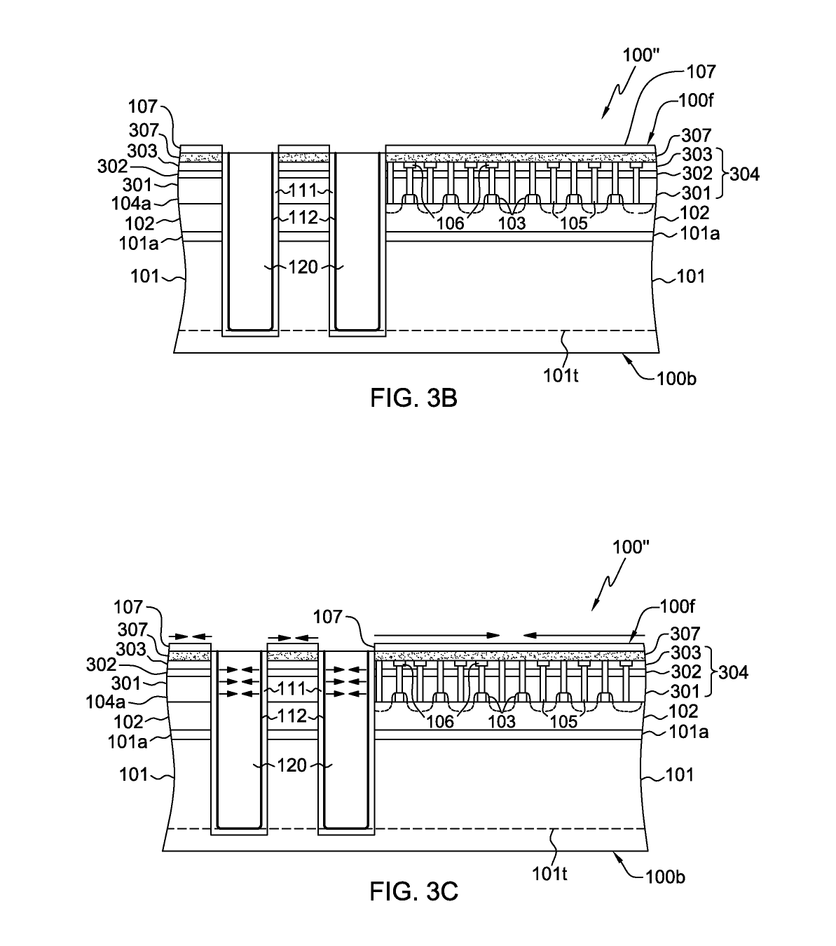

Referring to FIG. 3A, one embodiment of a structure 100′, such as a wafer, is provided similar to wafer 100 described above in connection with FIGS. 1A-1F, except for certain below-described modifications thereof. In this example, structure 100′ is shown to lack a device keep-out zone (KOZ) between through-substrate via 120 and the adjacent devices of device layer 102. This is achieved by cancelling or significantly reducing any stress within the device layer 102 caused by the presence of through-substrate via(s) 120 within the substrate. By way of example, hardmask layer 107 described above overlies a stress-offset layer 307 in the example of FIG. 3A. In one embodiment, stress-offset layer 307 may also function as an etch-stop layer for the above-described polishing of the structure.

By way of example, the stress cancellation or reduction within the substrate provided by the overlying stress offset layer can be controlled to reduce or eliminate the device keep-out zone adjacent to the through-substrate via(s) by tailoring or selecting the material used in the stress-offset layer, as well as by appropriately sizing the stress-offset layer (which as noted, may also function in certain embodiments as an etch-stop layer for a chemical-mechanical polishing operation). For instance, the stress-offset layer may be selected to have a high coefficient of thermal expansion, closer to the CTE of the through-substrate via material. By way of further example, the coefficient of thermal expansion of the stress-offset layer may be N times greater than the coefficient of thermal expansion of the substrate, wherein N≧2. The product of the coefficient of thermal expansion of the stress-offset layer and an elasticity modulus of the semiconductor material of the substrate is at least 1.5 times greater than the product of coefficient of thermal expansion of the semiconductor material of the substrate, and an elasticity modulus of the stress-offset layer. By way of example, the elasticity modulus of the stress-offset layer may be 200 MPa, or less. By way of specific example, the stress-offset layer may be a nitrogen-doped and hydrogen-doped silicon carbide, such as N-Blok, and have a coefficient of thermal expansion mismatch with the substrate, which is approximately three (3) times higher than that of a conventional silicon carbide etch-stop layer. Additionally, a nitrogen-based silicon carbide stress-offset layer has an approximately ⅓ lower elasticity modulus (e.g., 167 vs. 450 MPa). As noted, in one example, the stress-offset layer may be N-Blok, which has a CTE of 11 ppm/° C. This stress-offset layer, however, can be replaced by any stress-compensating dielectric material with a coefficient of thermal expansion well higher than the underlying semiconductor material, and an elasticity modulus less than, for instance, 200 MPa.

Experimental results have confirmed that providing a stress-offset layer designed as disclosed herein can result in negligible effects on the adjacent device performance due to through-substrate via stress. This can be achieved with a stress-offset layer, in accordance with one or more aspects of the present invention, which has a coefficient of thermal expansion greater than approximately three times that of the underlying substrate, and more particularly, that of the semiconductor material of the device layer within the substrate, and an elasticity modulus which is approximately 200 MPa or less. As a specific example, the stress-offset layer may have a coefficient of thermal expansion (CTE) three (3) times or more the CTE of the semiconductor material of the substrate. Any dielectric layer meeting these characterizations may function as a stress-compensation dielectric layer or stress-offset layer, as described herein.

Note that, advantageously, in one embodiment, the stress-offset layer disclosed herein remains within the resultant structure and facilitates reducing stress within the structure during normal operation of the structure. Also, depending on the polishing process, the stress-offset layer (that is when functioning as an etch-stop layer), may be partially removed during the CMP, and if desired, the removed portion may be replaced after the polishing to achieve a desired thickness for the layer, for instance, in the range of 10-40 nm

The concepts disclosed herein may be employed with a variety of substrates and through-substrate via configurations. FIG. 3B depicts one such variation, wherein a structure 100″ is presented similar to structure 100′ of FIG. 3A, but with the contact structure layer 104 of FIG. 3A replaced with multiple layers of dielectric material as part of the contact structure layer 304. For instance, in one embodiment, device layer 102 may include silicon, and the multiple dielectric layers of contact structure layer 304 may include an oxide layer 301 over the device layer 102, a nitride layer 302 over oxide layer 301, and a TEOS layer 303 over nitride layer 302, as illustrated. Other middle-of-line (MOL) layers may be substituted within or used in associated with, for instance, contact structure layer 304, as desired. Notwithstanding the underlying structure, the stress-offset layer may be selected, tailored, or configured, to control the desired offset stress induced within, for instance, device layer 102, to offset any stress within device layer 102 due to the presence of through-substrate via(s) 120 extending through the substrate.

For instance, as shown in FIG. 3C, the through-substrate via(s) 120 may produce a thermally-induced tensile stress within device layer 102, which is offset by the stress-offset layers' thermally-induced compressive stress, which extends down into device layer 102. The desired result is that the sum of the stresses within device layer 102 is significantly reduced, or even almost zero, directly adjacent to the through-substrate via(s) 120. This allows for elimination of the device keep-out zone (KOZ) around the through-substrate via(s), meaning that the through-substrate via(s) will have little or no impact on the adjacent devices of the device layer. Note that the concepts disclosed herein are independent of the through-substrate via diameter, as well as independent of its configuration. The stress-offset layer disclosed herein may be extended to any technology node, and will allow for higher device packing density within the device layer, and therefore better device performance, by removing the need for the conventional device keep-out zone around the through-substrate via(s). In particular, the typical negative impact on device I_{ON} is eliminated by balancing the stresses within the device layer through selection, tailoring and/or configuration of the stress-offset layer disclosed herein.

By way of further example, FIGS. 4A-4E depict, in part, a process flow for forming a structure with one or more through-substrate vias (TSVs) and a stress-offset layer, in accordance with one or more aspects of the present invention.

Referring to FIG. 4A, a structure 400 is shown which is an intermediate structure obtained during middle-of-line processing, in accordance with the concepts disclosed herein. As depicted, structure 400 includes a substrate 401, which may comprise a semiconductor material, and an active region (or device layer) 402 comprising multiple circuit elements, such as multiple N-channel Field-Effect Transistors (NFETs) and P-channel Field-Effect Transistors (PFETs) devices. The middle-of-line layers include, in one example, alternating oxide and nitride layers 403, above which a TEOS layer 404 is provided. Pursuant to aspects of the present invention, a stress-offset layer 407 is disposed over TEOS layer 404. Stress-offset layer 407 is selected and configured (e.g., sized) to advantageously provide a desired offset stress to cancel or reduce stress within the substrate, as described herein. In one example, this stress-offset layer may be a nitrogen-doped and hydrogen-doped silicon carbide material, such as N-Blok (also referred to as nitride barrier for low-K), which typically has 10% mol to about 25% mol of nitrogen dopant, and which may be deposited using, for instance, chemical vapor deposition (CVD) processing. A thin nitride layer 408 overlies stress-offset layer 407, and protects stress-offset layer 407 during ashing of the photoresist (see below) employed in patterning one or more through-substrate vias to extend through the substrate.

As illustrated in FIG. 4B, a resist layer 410 is patterned with one or more openings 411, exposing the nitride layer 408. In FIG. 4C, the patterned resist is employed in etching through the middle-of-line layers and into the substrate, which as noted above, may be or comprise, for instance, a semiconductor material such as silicon.

In FIG. 4D, the structure of FIG. 4C is illustrated, after removal of the resist, at which point the thin nitride 408 remains, and (by way of example) barrier and work function layers have been formed within the through-substrate via opening 411′ (see FIG. 4C), and a conductive material 412 is formed over the wafer so as to completely fill the through-substrate via opening(s) and overlie the structure, as shown in FIG. 4D.

In FIG. 4E, chemical-mechanical polishing has been employed to remove the overburden conductive material 412, which also removes the thin nitride 408 (see FIG. 4D) and a portion of the exposed stress-offset layer 407′. After chemical-mechanical polishing, the stress-offset layer 407′ is re-deposited to establish a desired layer thickness and facilitate obtaining a desired stress-offset in the underlying structures. In one example, 10-15 nm of stress-offset material may be deposited after polishing to remove the TSV overburden from the structure.

FIG. 4F depicts an alternate structure 400′ to that described above in connection with FIGS. 4A-4E. This alternate structure is obtained substantially as described above, with the exception that the TSV opening is provided with an angled region in the upper portion thereof, with the entrant angle θ being in the range of, for instance, 45° to 90°. In this implementation, the stress-relieving layer 407′ may be tailored to accommodate the resultant modified stress in the substrate resulting from the angling of the TSV 412′.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

What is claimed is:

1. A method comprising:
forming a structure with a through-substrate via (TSV) and a reduced device keep-out zone (KOZ) adjacent to the through-substrate via, the forming comprising:
providing the through-substrate via within a substrate of the structure; and
providing a stress-offset layer above the substrate selected and configured to provide a desired offset stress to reduce stress within the substrate caused by the presence of the through-substrate via within the substrate.

2. The method of claim 1, wherein providing the stress-offset layer comprises selecting the stress-offset layer to provide the desired offset stress to substantially eliminate the stress within the substrate caused by the presence of the through-substrate via within the substrate.

3. The method of claim 1, wherein the stress-offset layer is selected and configured to reduce thermally-induced stress within the substrate caused by a mismatch of coefficients of thermal expansion between the substrate and the through-substrate via.

4. The method of claim 1, wherein the forming further comprises annealing the structure, and wherein post-annealing, the stress-offset layer shrinks at a faster rate than the substrate, providing a thermally-induced compressive stress within the substrate which offsets a thermally-induced tensile stress within the substrate adjacent to the through-substrate via.

5. The method of claim 1, wherein the substrate comprises a semiconductor material, and a coefficient of thermal expansion of the stress-offset layer is N times greater than a coefficient of thermal expansion of the semiconductor material, wherein N≧2.

6. The method of claim 5, wherein the product of the coefficient of thermal expansion of the stress-offset layer and an elasticity modulus of the semiconductor material is at least 1.5 times greater than the product of the coefficient of thermal expansion of the semiconductor material and an elasticity modulus of the stress-offset layer.

7. The method of claim 6, wherein the elasticity modulus of the stress-offset layer is less than 200 MPa.

8. The method of claim 7, wherein the stress-offset layer comprises a nitrogen-doped and hydrogen-doped silicon carbide, Si_{w}CₓN_{y}H_{z}, where w+x+y+z=1.0, the semiconductor material comprises silicon, and the through-substrate via comprises copper.

9. The method of claim 1, wherein the desired offset stress is a thermally-induced compressive stress within the substrate which substantially cancels out a thermally-induced tensile strain within the substrate produced by the presence of the through-substrate via within the substrate.

10. The method of claim 1, wherein the forming further comprises polishing the structure, and stopping the polishing on the stress-offset layer, wherein the stress-offset layer is an etch-stop layer for the polishing of the structure.

11. The method of claim 10, wherein the forming further comprises annealing the structure, and wherein post-annealing, the stress-offset layer shrinks at a faster rate than the substrate, providing the desired offset stress as a compressive stress within the substrate which offsets a tensile stress within the substrate adjacent to the through-substrate via.

12. A structure comprising:
a substrate;
a through-substrate via (TSV) extending through the substrate;
a device disposed adjacent to the through-substrate via without a thermal-stress-necessitated, keep-out zone disposed between the through-substrate via and the device; and
a stress offset layer above the substrate, the stress-offset layer providing a desired offset stress to cancel thermally-induced stress in the substrate adjacent to the through-substrate via, and thereby eliminate need for the thermal-stress-necessitated, keep-out zone between the through-substrate via and the device.

13. The structure of claim 12, wherein the device is disposed five microns or less from the through-substrate via.

14. The structure of claim 12, wherein the through-substrate via extending through the substrate has an upper entrant angle in the range from 45° to 90°.

15. The structure of claim 12, wherein the substrate comprises a semiconductor material, and a coefficient of thermal expansion of the stress-offset layer is N times greater than a coefficient of thermal expansion of the semiconductor material, wherein N≧2.

16. The structure of claim 15, wherein the product of the coefficient of thermal expansion of the stress-offset layer and an elasticity modulus of the semiconductor material is at least 1.5 times greater than the product of the coefficient of thermal expansion of the semiconductor material and an elasticity modulus of the stress-offset layer.

17. The structure of claim 16, wherein the elasticity modulus of the stress-offset layer is less than 200 MPa.

18. The structure of claim 17, wherein the stress-offset layer comprises a nitrogen-doped and hydrogen-doped silicon carbide, Si_{w}CₓN_{y}H_{z}, where w+x+y+z=1.0, the semiconductor material comprises silicon, and the through-substrate via comprises copper.

19. The structure of claim 12, wherein the desired offset stress is a thermally-induced compressive stress within the substrate which substantially cancels thermally-induced tensile stress within the substrate due to the presence of the through-substrate via, thereby allowing elimination of the keep-out zone between the through-substrate via and the device.

20. The structure of claim 12, wherein the device is an active device disposed adjacent to the through-substrate via within five microns or less therefrom.
